(19) United States
(12) Patent Application Publication
(10) Pub. No.: US 2016/0091541 A1
(43) Pub. Date: Mar. 31, 2016

(54) PARAMETER DETERMINATION METHOD, COMPUTER-READABLE RECORDING MEDIUM, AND INFORMATION PROCESSING APPARATUS

(71) Applicant: FUJITSU LIMITED, Kawasaki-shi (JP)

(72) Inventors: Yoshinobu Matsui, Kawasaki (JP); Hirokazu Anai, Hachioji (JP); Hidenao Iwane, Kawasaki (JP)

(21) Appl. No.: 14/854,132

(22) Filed: Sep. 15, 2015

(30) Foreign Application Priority Data
Sep. 29, 2014 (JP) 2014-198595

(51) Int. Cl. G01R 23/00

(52) U.S. Cl. CPC G01R 23/00

(57) ABSTRACT

A parameter determination method is disclosed. Information of specification of the output is received. A first circuit constant and a second circuit constant to set in elements forming an equivalent circuit of the predetermined circuit is received. A first range of a plurality of the parameters which are to be set in a compensator that compensates the output is specified based on the information of the specification and the first circuit constant. A second range of a plurality of parameters which are to be set in the compensator is specified based on the information of the specification and the second circuit constant. At least one of a parameter included in both the first range and the second range.

### CROSS-REFERENCE TO RELATED APPLICATIONS

This application is based upon and claims the benefit of priority of the prior Japanese Priority Application No. 2014-198595 filed on Sep. 29, 2014, the entire contents of which are hereby incorporated by reference.

### FIELD

The embodiment discussed herein is related to a parameter determination method, a computer-readable recording medium, and an information processing apparatus.

### BACKGROUND

Recently, a DC-DC converter by software control using a processor such as a DSP (Digital Signal Processor) or the like has been widely used to supply stable power to an electronic device.

Regarding the software control by the DSP or the like, one of technologies is proposed in which an output impedance of the DC-DC converter is variably controlled, an actual output impedance is estimated, and parameters for a phase compensator are changed. Another technology is presented in which current flowing through a choke coil of the DC-DC converter is monitored, an actual output capacitance is estimated, and the parameters for the phase compensator are changed.

### PATENT DOCUMENTS

Japanese Laid-open Patent Publication No. 2009-72004

Japanese Laid-open Patent Publication No. 2009-72005

### SUMMARY

According to one aspect of the embodiment, there is provided parameter determination method including: receiving information of a specification required for an output of a predetermined circuit; receiving a first circuit constant and a second circuit constant which are set in elements included in an equivalent circuit of the predetermined circuit; specifying, by a computer, a first range of a plurality of parameters which are to be set in a compensator that compensates the output based on the information of the specification and the first circuit constant; specifying, by the computer, a second range of a plurality of parameters which are to be set in the compensator based on the information of the specification and the second circuit constant; and outputting, by the computer, at least one of a parameter included in both the first range and the second range.

According to other aspects of the embodiment, a program and an information process apparatus may be provided.

The object and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a diagram illustrating a circuit configuration example of a power unit;

FIG. 2 is a diagram illustrating a state of an output voltage Vₒᵤₜ;

FIG. 3 is a diagram illustrating an example of an equivalent circuit of a DC-DC converter;

FIG. 4 is diagrams for explaining a relationship between an operation of a switch S and the output voltage Vₒᵤₜ;

FIG. 5 is a diagram illustrating an example of a model by a transfer function;

FIG. 6 is a diagram for explaining a frequency characteristic specification;

FIG. 7 is a diagram illustrating a Bode plot of the frequency characteristic L(jω);

FIG. 8 is a diagram illustrating an example of a location of a fixed point;

FIG. 9 is a diagram illustrating calculation results of frequency characteristics by a DSP;

FIG. 10 is a diagram illustrating a hardware configuration of an information processing apparatus;

FIG. 11 is a diagram illustrating a brief configuration of the information processing apparatus;

FIG. 12 is a diagram illustrating a functional configuration example of the information processing apparatus;

FIG. 13 is a diagram for explaining an example of a parameter determination process;

FIG. 14 is a flowchart for explaining another example of a parameter determination process;

FIG. 15 is a flowchart for explaining a determination process;

FIG. 16 is a diagram illustrating a program description example for conducting a process in step S33 in FIG. 15;

FIG. 17A and FIG. 17B are diagrams illustrating calculation results of parameter regions Rc and Rd for each of manufacture dispersions;

FIG. 18A and FIG. 18B are diagrams for explaining a calculation result example of a common region ARd;

FIG. 19A, FIG. 19B, and FIG. 19C are diagrams illustrating result examples of lattice points based on the LSB intervals; and

FIG. 20A and FIG. 20B are diagrams of another calculation result example of the common region ARd.

### DESCRIPTION OF EMBODIMENTS

In the related art, in order for a DC-DC converter to achieve a desired control performance, a Digital Signal Processor (DSP) adjusts phase compensator parameters so that frequency characteristics of the open loop transfer function satisfy specifications for respective frequency bands. The phase compensator parameters are adjusted accompanied by tests and disclosed faults by a developer at a design stage. In a case of mass production of the DC-DC converters, the phase compensator parameters are further adjusted due to manufacturing dispersion.

Furthermore, the DSP connected to the DC-DC converter actually changes parameters (phase compensator parameters) to compensate a phase of an output voltage. Accordingly, before producing the DC-DC converters in large quantities, it is difficult to determine the phase compensator parameters in consideration of the manufacture dispersion. The phase compensator parameters are re-adjusted by the developer for each of produced DC-DC converters.

However, in an embodiment, a parameter determination method, a computer-readable recording medium, and an information processing apparatus are presented to easily determine compensator parameters.

In the following, the embodiment of the present invention will be described with reference to the accompanying drawings.

First, control of the DC-DC convertor by a processor such as the DSP (Digital Signal Processor) or the like will be described. Hereinafter, the processor is simply called “DSP”. In the embodiment, a DC-DC back convertor is described. However, the embodiment is not limited to the DC-DC back convertor, and is capable of being applied to various types of DC-DC converters.

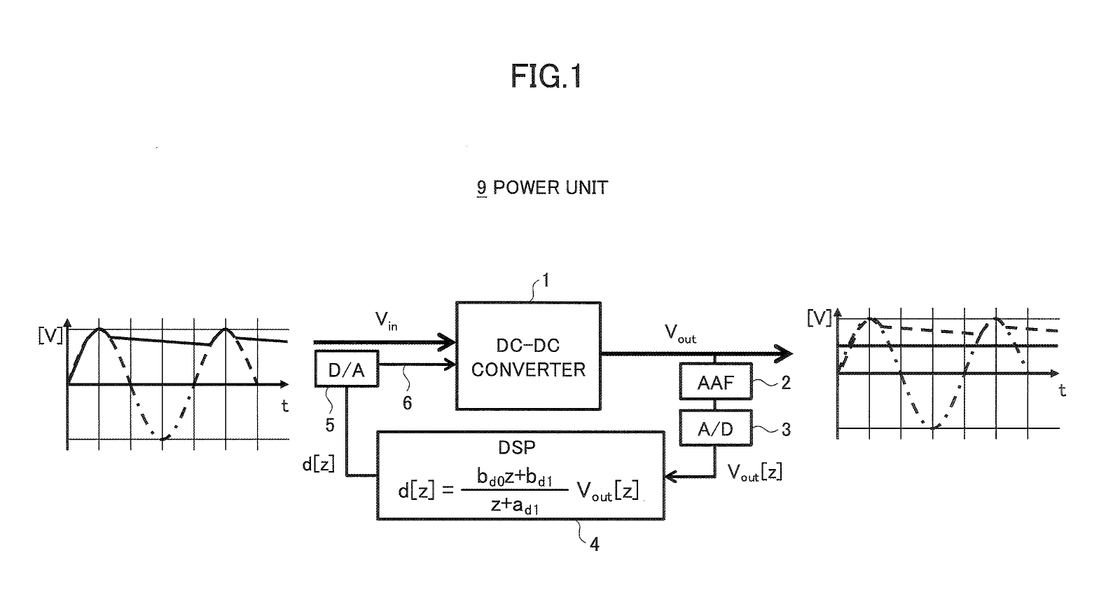

FIG. 1 is a diagram illustrating a circuit configuration example of a power unit. In FIG. 1, a power unit 9 includes a DC-DC convertor 1, an AAF (Anti-Aliasing Filter) 2, an A-D (Analog to Digital) convertor 3, a DSP 4, and a D-A (Digital to Analog) convertor 5.

The DC-DC convertor 1 is a conversion circuit which outputs an output voltage Vₒᵤₜ to be a voltage in which an input voltage Vᵢₙ is defined beforehand. The output voltage Vₒᵤₜ from the DC-DC convertor 1 is supplied to a device in an electronic device and is also input to the AAF 2 to compensate the phase of the output voltage Vₒᵤₜ being sampled.

The AAF 2 is a filter which eliminates excess frequency components from a sampled frequency of the output voltage Vₒᵤₜ of the DC-DC convertor. The output voltage Vₒᵤₜ, in which the excess frequency components are eliminated, is input to the A-D convertor 3. The A-D convertor 3 converts the output voltage Vₒᵤₜ being input from the AAF 2 from analog to digital, and inputs the converted voltage Vₒᵤₜ[Z] to the DSP 4.

The DSP 4 corresponds to a digital phase compensator, compensates a phase with respect to the voltage Vₒᵤₜ[Z], and outputs the voltage Vₒᵤₜ[Z] to the D-A convertor 5. A voltage signal output to the D-A convertor 5 is represented by d[z].

The D-A convertor 5 converts the voltage signal d[z] to acquire a control signal 6, and inputs the control signal 6 to the DC-DC converter 1. The DC-DC converter 1 outputs the output voltage Vₒᵤₜ which is stable by controlling an internal operation, in accordance with the control signal 6.

In the above described circuit configuration of the power unit 9, the DSP 4, which outputs the stable output voltage Vₒᵤₜ from the DC-DC converter 1, may be represented as follows:

$$d [ z ] = \frac{{b}_{d 0} z + {b}_{d 1}}{z + {a}_{d 1}} {V}_{out} [ z ] . \qquad [ expression 1 ]$$

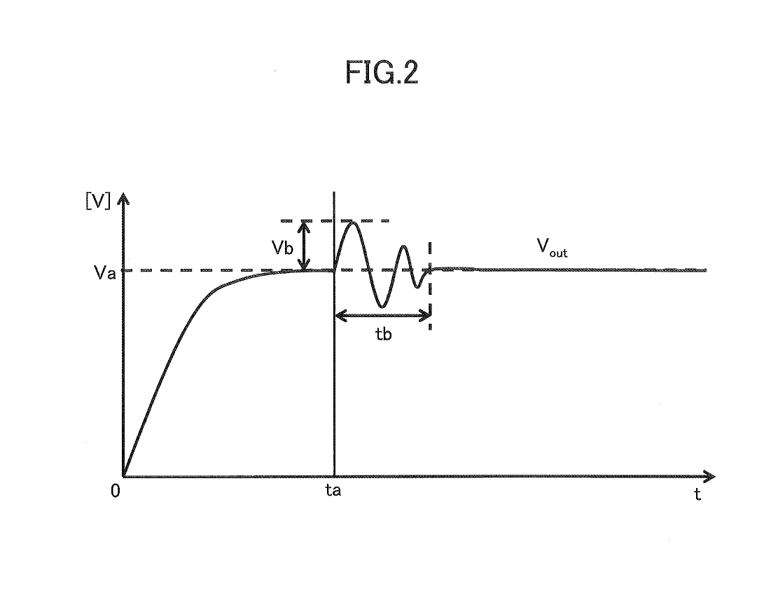

A purpose of controlling the DC-DC converter 1 will be described. FIG. 2 is a diagram illustrating a state of the output voltage Vₒᵤₜ. In a graph in FIG. 2, a longitudinal axis indicates voltage, and a lateral axis indicates time.

A time ta indicates a time when load is rapidly changed in order to follow the output voltage Vₒᵤₜ to a desired voltage Va due to a rise in the output voltage Vₒᵤₜ. A time tb indicates a stabilization time from the time ta when the load is rapidly changed until the output voltage Vₒᵤₜ becomes stable and the desired voltage Va is retained. Due to a rapid change of the load, the output voltage Vₒᵤₜ may overshoot higher than the desired voltage Va.

The DSP 4 causes the output voltage Vₒᵤₜ of the DC-DC converter 1 to follow the desired voltage Va, and persistently controls the DC-DC converter 1 to retain a desired voltage level even if the load is rapidly changed. That is, first, the DSP controls the DC-DC converter 1 to maintain a voltage difference Vb causing the overshoot to be lower. Second, the DSP controls the DC-DC converter 1 to shorten the stabilization time tb. The above described controls are defined by a specification indicating values for the power unit 9 to be produced.

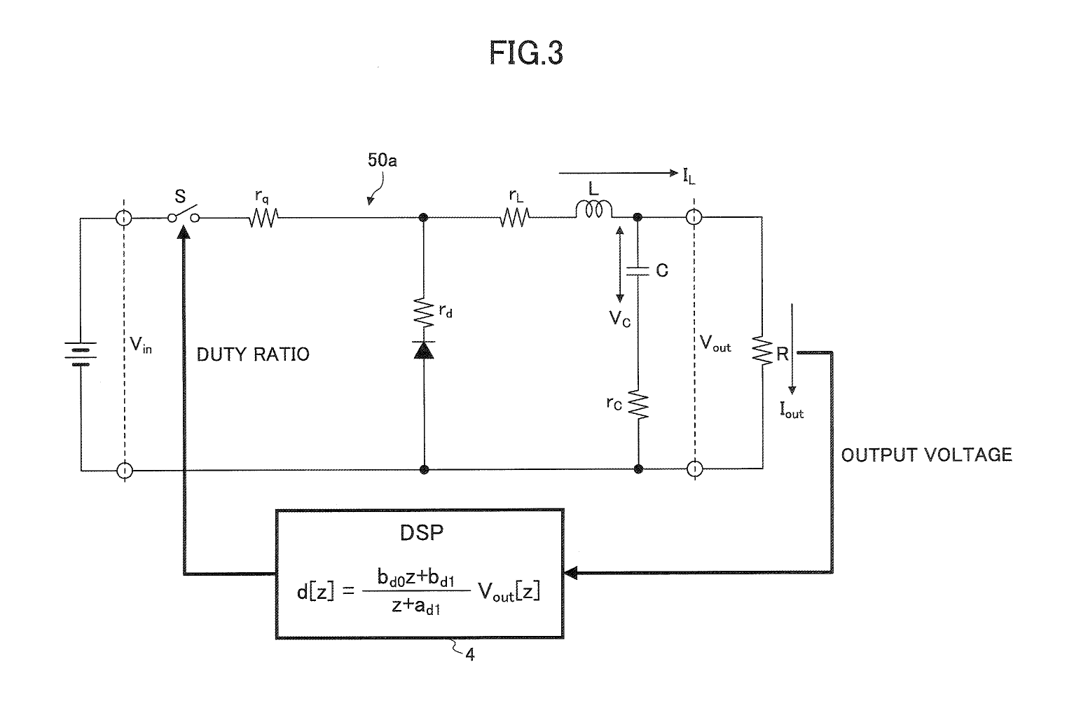

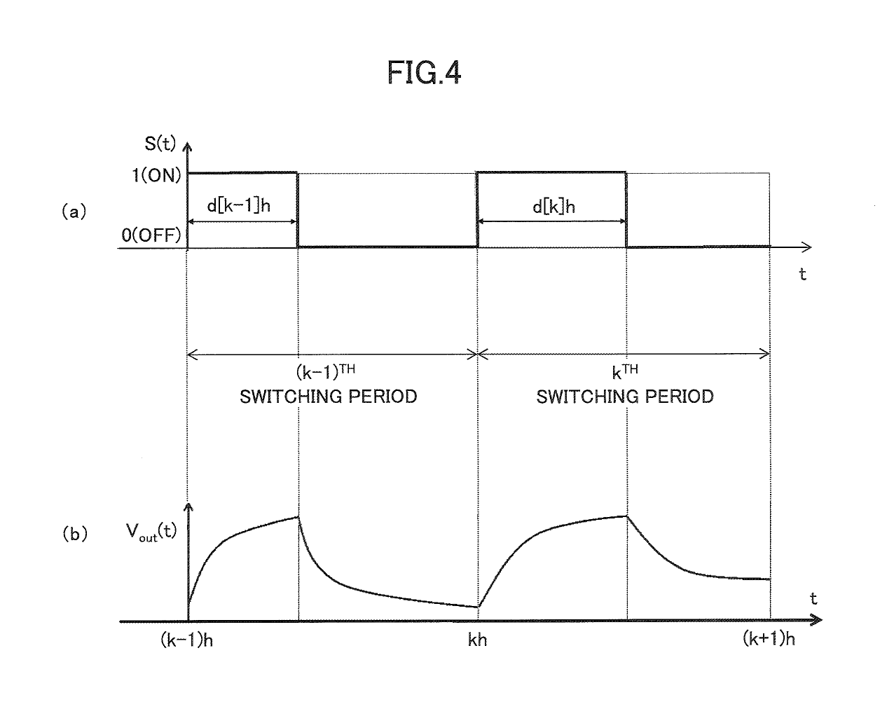

Next, a control principle of the DSP 4 in order to achieve the above described control purpose will be described with reference to FIG. 3 and FIG. 4. First, operations of the DC-DC converter 1 will be described. FIG. 3 is a diagram illustrating an example of an equivalent circuit of the DC-DC converter. In FIG. 3, an equivalent circuit 50a of the DC-DC converter 1 is illustrated.

When a switch S is ON, current of a power source Vᵢₙ is prevented flowing due to an inductance L of a coil. Since an input voltage Vᵢₙ being from an input side is negated, the voltage V is dropped, and electric charge is accumulated in a capacitor C. Current of the voltage V becomes current I_{L}. A resistor r_{q} represents an internal resistance of the switch S. A resistor r_{L} represents a resistance of the coil.

When a magnetic flux of the inductance L, which is generated since the switch S is ON, is diminished, the voltage is supplied to the capacitor C due to current reflux caused by the capacitor C and a diode (operational resistor r_{d}) even if the switch S is OFF. Accordingly, the output voltage Vₒᵤₜ of a direct voltage is consecutively supplied to a load R. A resistor r_{c} represents a resistance of the capacitor C. The diode is represented by the operational resistor r_{d}.

In order to stabilize an output of the DC-DC converter 1, the output voltage Vₒᵤₜ is fed back to the DSP 4. The DSP 4 monitors the output voltage Vₒᵤₜ, and controls a duty ratio when the switch S is ON or OFF.

FIG. 4 is diagrams for explaining a relationship between an operation of the switch S and the output voltage Vₒᵤₜ. In FIG. 4, (a) depicts S(t) representing an operation of the switch S, and (b) depicts the output voltage Vₒᵤₜ(t).

S(t), which repeats ON and OFF as a term between ON and OFF is regarded as one switching period, is expressed by the following expression 2.

$$S ( t ) = \{ \begin{matrix}1 , & kh \leq t < ( k + d [ k ] ) h , \\ 0 , & ( k + d [ k ] ) h \leq t < ( k + 1 ) h ,\end{matrix} \qquad \{ Expression 2 ]$$

In the above expression 2, t denotes a consecutive time, k denotes a discrete time, h denotes a constant switching interval, and d[k] denotes the duty ratio. d[k] denotes a ratio of an on term in a k-th switching period, where k is positive number. In (k−1)-th switching period, the ON term is expressed by d[k−1]h when using the duty ratio. Similarly, in the k-th switching period, the ON term is expressed by d[k]h.

Due to the operation of the switch S expressed by S(t), the voltage is increased when the switch S is ON, and the voltage is decreased when the switch S is OFF. The voltage varies such as the output voltage Vₒᵤₜ(t) illustrated in (b) of FIG. 4. The DSP 4 achieves the above described control purpose by adjusting the switching interval between ON and OFF, that is, d[k]. Hereinafter, d[k] may be described as the switching interval d[k].

That is, the DSP 4 is designed to adjust the switching interval d[k] in order to achieve the above described control purpose. To control the DC-DC converter 1 by the switching interval d[k] for achieving the control purpose, the parameters of the digital phase compensator realized by the DSP 4 are adjusted. The parameters of the digital phase compensator are b_{d0}, b_{d1}, and a_{d1} in the above described expression 1. The parameters b_{d0}, b_{d1}, and a_{d1} are the scalars.

That is, to achieve the control purpose, the parameters of the digital phase compensator are adjusted so as to satisfy a given specification of the frequency characteristics. In the following, a first stage will be described as a stage in which the parameters of the digital phase compensator are determined.

First Stage

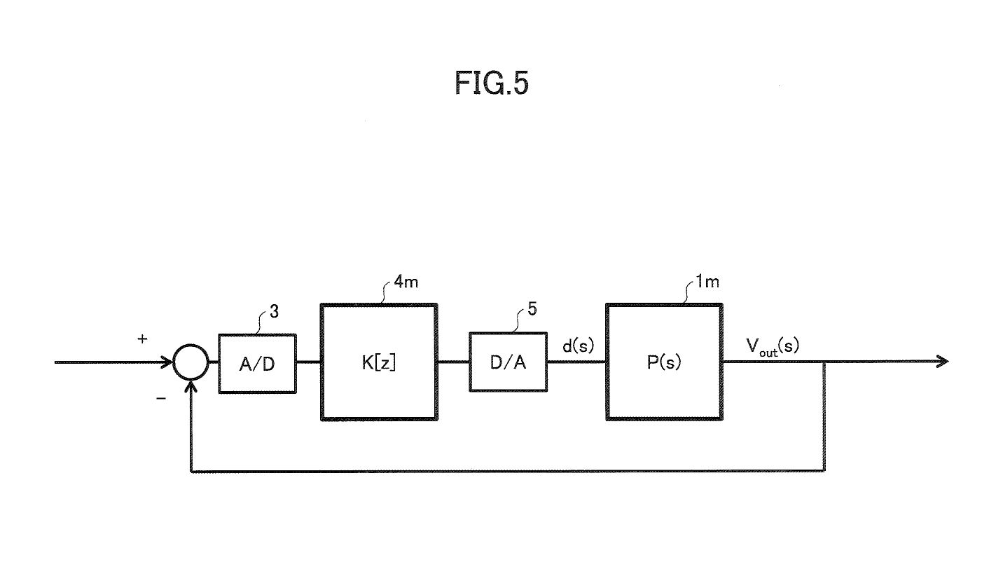

Each of the DC-DC converter 1 and the DSP 4 in the power unit 9 is expressed by a transfer function, and a frequency characteristic (g-φ characteristic) of the open loop transfer function in the power unit 9 is analyzed. FIG. 5 is a diagram illustrating an example of a model of the transfer function. In FIG. 5, a DC-DC converter model 1m is expressed by a transfer function P(s) including a control system, and a phase compensator model 4m is expressed by a pulse transfer function K[z]. The phase compensator 4m corresponds to the digital phase compensator function performed by the DSP 4.

A method, which derives the transfer function P(s) from the equivalent circuit 50a of the DC-DC converter 1 depicted in FIG. 3, will be described.

Procedure 1: A switching state space model is derived. The switching state space model is created by using a circuit equation such as Kirchhoff's rule or the like from the equivalent circuit 50a.

A state is expressed as follows:

x(t):=[I_{L}(t) V_{C}(t)]^{T}. [Expression 3]

The switching state space model is expressed by the following expressions:

$$\begin{matrix}\frac{d}{d t} x ( t ) = \{ \begin{matrix}{A}_{1} x ( t ) + {B}_{1} {V}_{in} , & S ( t ) = 1 , \\ {A}_{2} x ( t ) , & S ( t ) = 0 ,\end{matrix} \\ and & [ Expression 4 ] \\ {V}_{out} ( t ) = \{ \begin{matrix}{C}_{V} x ( t ) , & S ( t ) = 1 , \\ {C}_{V} x ( t ) , & S ( t ) = 0 ,\end{matrix} & [ Expression 5 ]\end{matrix}$$

The expressions 4 and 5 include the following matrixes represented by circuit constants.

$$\begin{matrix}{A}_{1} := [ \begin{matrix}- \frac{( {r}_{q} + {r}_{L} + α {r}_{C} )}{L} & - \frac{α}{L} \\ \frac{α}{C} & - \frac{α}{CR}\end{matrix} ] , & [ Expression 6 ] \\ {A}_{2} := [ \begin{matrix}- \frac{( {r}_{d} + {r}_{L} + α {r}_{C} )}{L} & - \frac{α}{L} \\ \frac{α}{C} & - \frac{α}{CR}\end{matrix} ] , α := \frac{R}{R + {r}_{C}} & \\ {B}_{1} := [ \begin{matrix}\frac{1}{L} \\ 0\end{matrix} ] , {C}_{V} := \begin{matrix}⌈ α {r}_{C} & α ⌉\end{matrix} . & \end{matrix}$$

Procedure 2: d[k] is regarded as approximately d(t).

d[k]˜d(t) [Expression 7]

An average is acquired within one period (the switching interval h ((a) and (b) in FIG. 4).

In detail, first, d(t) is multiplied when the switch S is ON, and (1-d(t)) is multiplied when the switch S is OFF. With respect to the expression 4,

$$\frac{d}{d t} x ( t ) = \{ \begin{matrix}( {A}_{1} x ( t ) + {B}_{1} {V}_{in} ) \times d ( t ) , & S ( t ) = 1 , \\ ( {A}_{2} x ( t ) ) \times ( 1 - d ( t ) ) , & S ( t ) = 0 ,\end{matrix} \qquad [ Expression 8 ]$$

Also, with respect to the expression 5, the following expression 9 is acquired.

$${V}_{out} ( t ) = \{ \begin{matrix}( {C}_{V} x ( t ) ) \times d ( t ) , & S ( t ) = 1 , \\ ( {C}_{V} x ( t ) ) \times ( 1 - d ( t ) ) , & S ( t ) = 0 ,\end{matrix} \qquad [ Expression 9 ]$$

Then, the following averages are acquired within one period in the expressions 7 and 8, respectively.

$$\frac{d}{d t} x ( t ) = ( {A}_{1} d ( t ) + ( 1 - d ( t ) ) {A}_{2} x ) + {B}_{1} {V}_{in} d ( t ) \qquad [ Expression 10 ]$$

Vₒᵤₜ(t)=C_{V}x(t) [Expression 11]

Procedure 3: The Laplace transform is conducted.

Y(s):= [symbol] [y(t)], U(s):= [symbol] [u(t)],

X(s):= [symbol] [x(t)], P(s):=C(sI−A)⁻B,

P: Y(s)=P(s)U(s) [Expression 12]

From the expression 11, the transfer function P(s) is acquired.

$$P ( s ) = \frac{{b}_{0} {s}^{n} + {b}_{1} {s}^{n - 1} + ⋯ + {b}_{n}}{{s}^{n} + {a}_{1} {s}^{n - 1} + ⋯ + {a}_{n}} \qquad [ Expression 13 ]$$

In the expression 12, all coefficients are real numbers (scalars). With respect to Laplace operator s of the transfer function P(s), jω is substituted, so that s=jω(j denotes an imaginary number and ω denotes a real number). Hence, a frequency response P(jω) is expressed as follows:

$$P ( j ω ) = \frac{{{b}_{0} ( j ω )}^{n} + {{b}_{1} ( j ω )}^{n - 1} + ⋯ + {b}_{n}}{{( j ω )}^{n} + {{a}_{1} ( j ω )}^{n - 1} + ⋯ + {a}_{n}} . \qquad [ Expression 14 ]$$

By the expression 14, the frequency characteristic of the open loop transfer function is expressed as follows:

L(jω)=P(jω)×K(e^{jωh}). [Expression 15]

In the expression 14, j denotes the imaginary number, ω denotes the frequency, and h denotes a sampling period. For the expression 14, it is assumed that a specifications pertinent to the frequency characteristics are given.

Specification 1: desired voltage level following capability may be defined as follows.

|L(jω)|>45 dB, 0<ω≦1 Hz. [Expression 16]

Specification 2: A noise tolerance may be defined as follows:

|L(jω)|>25dB, 1<ω≦100Hz [Expression 17]

Specification 3: An overshoot at the rapid change of the load is defined as follows:

ωₑᵣ>3 kHz. [Expression 18]

Specification 4: The stabilization time for the sudden change of the load and stabilization of the control system may be defined as follows:

PM>45°. [Expression 19]

General specifications are simply presented as the above specifications 1 through 4. Detailed specifications may be given by a developer.

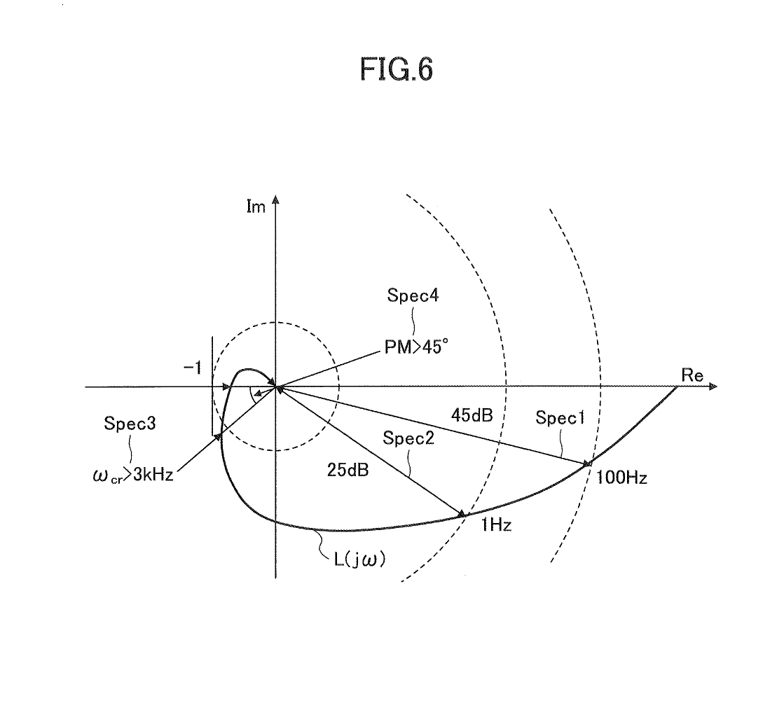

A frequency characteristic L(jω) is depicted on a complex plane as illustrated in FIG. 6. FIG. 6 is a diagram for explaining a frequency characteristic specification. In FIG. 6, with respect to the frequency characteristic L(jω) drawn on the complex plane, the specification 1 is represented by Spec1, the specification 2 is represented by Spec2, the specification 3 is represented by Spec 3, and the specification 4 is represented by Spec 4.

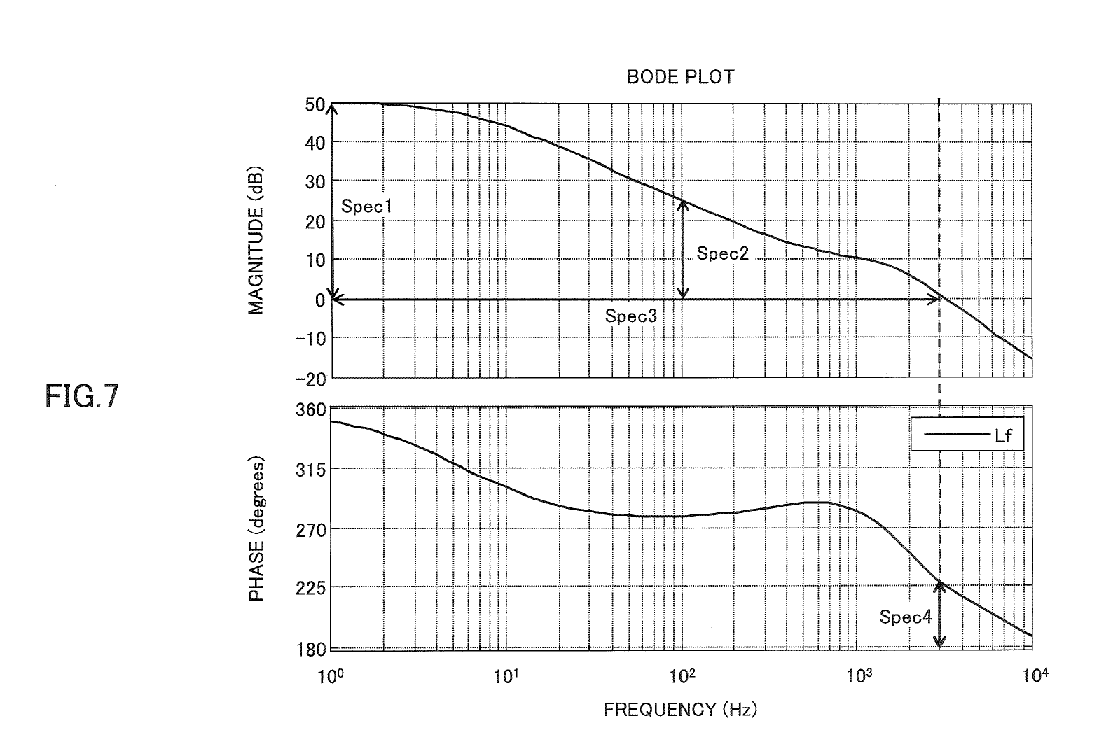

Also, FIG. 7 is a diagram illustrating the Bode plot of the frequency characteristic L(jω). In FIG. 7, at a magnitude plot, the Spec1, the Spec2, and the Spec3 depicted in FIG. 6 are indicated. Also, at a phase plot, the Spec 4 depicted in FIG. 6 is indicated.

Accordingly, the coefficients of the phase compensator model 4m are acquired so as to satisfy the above described specifications 1 through 4 with respect to the DC-DC converter 1. The phase compensator model 4m controlling the DC-DC converter 1 corresponds to a case of n=2 in the expression 12 and the expression 13. Hence, in the following expression 20,

$$K [ z ] = \frac{{b}_{d 0} z + {b}_{d 1}}{z + {a}_{d 1}} , \qquad [ Expression 20 ]$$

the coefficients b_{d0}, b_{d1}, and a_{d1} may be determined. As a result of trial and error, the developer determines the coefficients b_{d0}, b_{d1}, and a_{d1}. The coefficients b_{d0}, b_{d1}, and a_{d1} correspond to the parameters of the digital phase compensator implemented in the DSP 4. Hereinafter, the coefficients b_{d0}, b_{d1}, and a_{d1} are called the “parameters b_{d0}, b_{d1}, and a_{d1}”.

A second stage for implementing the parameters b_{d0}, b_{d1}, and a_{d1} will be described.

Second Stage

There is a restriction on parameters to implement to the DSP 4. The switching period h in the DC-DC converter 1 of the power unit 9 is significantly short. Hence, the DSP 4 needs to end an operation within this switching period h. For a higher arithmetic processing speed, a fixed point arithmetic operation is used for the DSP 4.

In a case of implementing the parameters b_{d0}, b_{d1}, and a_{d1} in the DSP 4, the developer verifies whether the DSP 4 has a control capability so as to satisfy the specifications 1 through 4 for the frequency characteristics. Mainly, the developer conducts verification of a bit number of the DSP 4, and verification of a location of the fixed point in the bit number for an accurate control.

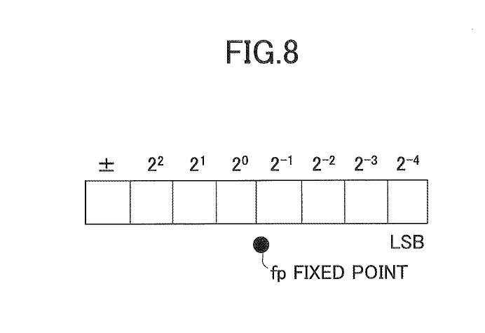

FIG. 8 is a diagram illustrating an example of the location of the fixed point. In FIG. 8, a location example of a fixed point fp is depicted in a case in which the DSP 4 is an 8 bit processor. In this example, the fixed point fp is defined at a fourth point left from a Least Significant Bit (LSB). This is a case in which the LSB is 2 ̂(−4), and a location of the fixed point fp is defined beforehand.

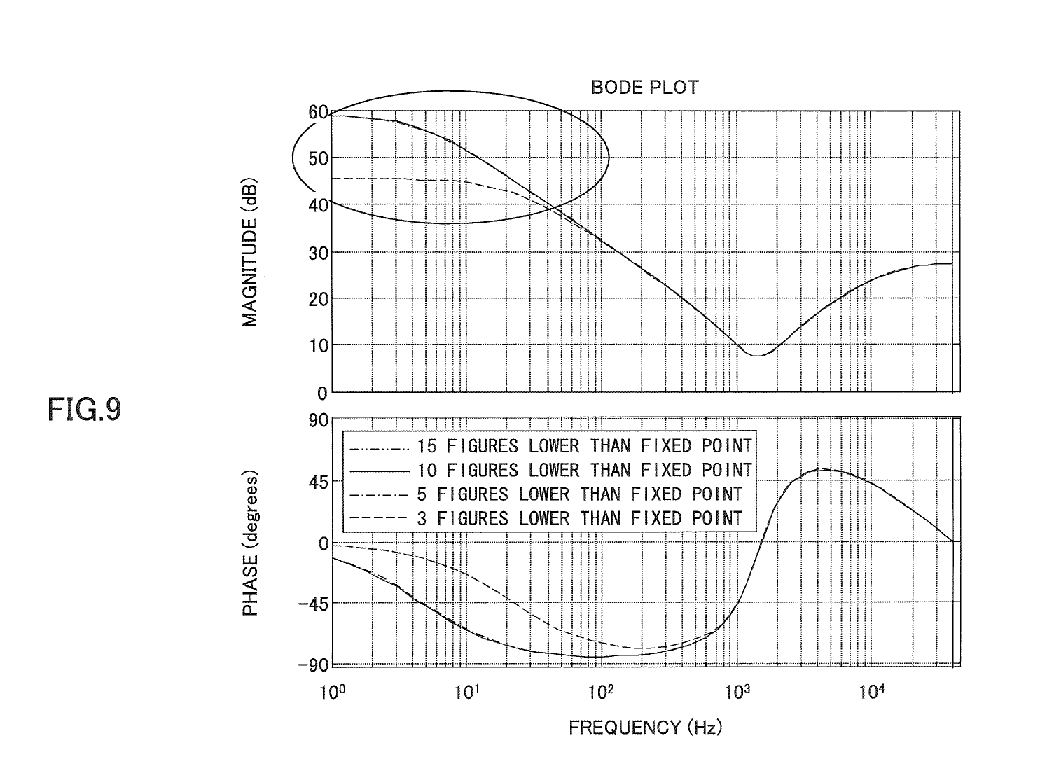

In a case in which the DSP 4 is a 16 bit processor, the location of the fixed point fp is defined beforehand, and the frequency characteristics are calculated. In this case, values of the parameters of the digital phase compensator, which are acquired at the first stage, are processed based on the fixed point fp within values implementable for the DSP 4. Calculation results of the frequency characteristics may be obtained as illustrated in FIG. 9.

FIG. 9 is a diagram illustrating the calculation results of the frequency characteristics by the DSP. In FIG. 9, the calculation results of the frequency characteristics are depicted by the Bode plot. This example illustrates the calculation results for respective cases in which the fixed point fp is set at a 3rd figure, a 5th figure, a 10th figure, and a 15th figure left from the LSB.

Referring to the magnitude plot of the Bode plot, when the fixed point fp is located at the 3rd figure left from the LSB, the specification 1 pertinent to the voltage level following capability is not satisfied. Thus, the fixed point fp may be set at the 5th figure, the 10th figure, or the 15th figure left from the LSB. In a case in which the bit number of the DSP 4 is 16 bits, the fixed point fp is preferably defined at the 5th figure or farther left from the LSB.

Third Stage

For verifying an adjustment of the digital phase compensator, MATrix LABoratory (MATLAB) for a numerical calculation may be used off-line. Thus, it is difficult to explicitly consider all details of the specifications of the DC-DC converter 1. Also, it is difficult to exclude the trial and error by the developer at the first stage. In addition, the numerical calculation using the MATLAB or the like is conducted by floating point arithmetic. Thus, it is difficult to exclude the trial and error based on experiences of the developer at the second stage.

Furthermore, the verifications at the first stage and the second stage are conducted for one DC-DC converter 1 as a target. Hence, manufacturing dispersion of the DC-DC converters 1 is not considered in a case of mass production. That is, in an apparatus that automatically adjusts the digital phase compensator in an on-line for each of the DC-DC converters 1 which are produced, the DSP 4 is separately adjusted for each of the DC-DC converters 1. In this case of using a model based on characteristics of each of the DC-DC converters 1, the first stage and the second stage are repeated.

In this embodiment, in the design of the digital phase compensator, by formulating and solving an optimization problem defining the specifications as constraints, the parameters of the digital phase compensator satisfying the specifications are acquired as an executable region of the optimization problem. That is, the specification 1, the specification 2, the specification 3, and the specification 4, which are described above, are regarded as the constraints, an objective function is set in which only the constraints are considered, and the executable region satisfying the constraints is acquired. In the embodiment, instead of an optimization, the executable region is acquired.

In consideration of the manufacturing dispersion of the DC-DC converters 1, the executable region corresponds to a region of the parameters b_{d0}, b_{d1}, and a_{d1} of the digital phase compensator which satisfies the specifications of the DC-DC converter 1.

First, since the specifications (constraints) of the DC-DC converter 1 are indicated by a non-convex function, a method for solving this optimization problem is limited.

In the embodiment, a Quantifier Elimination (QE) algorithm for handling the non-convex function and calculating an exact solution is used. In general, the QE algorithm is used for an analog circuit design alone, and the digital phase compensator is not designed by using the QE algorithm.

However, the inventor has found a method for acquiring the region of the parameters b_{d0}, b_{d1}, and a_{d1} of the digital phase compensator based on the manufacturing dispersion of the DC-DC converters 1 by designing the analog phase compensator by using the QE algorithm and by approximating the digital phase compensator. A parameter determination method according to the embodiment utilizes an advantage of the QE algorithm which realizes an accurate design for the analog phase compensator.

The following two problems may be raised in a case of using the QE algorithm.

### <Problem 1>

A calculation amount of the QE algorithm is known as a problem. In a case of designing the digital phase compensator in consideration of the manufacturing dispersion of the DC-DC converters 1, if the above described problems are simply formulated as an optimization problem, it is not possible to acquire the executable region within a practical time interval.

### <Problem 2>

It is not possible for the QE algorithm to handle an index function. That is, e^{jωh} in the expression 14, which represents the frequency characteristics of the open loop transfer function, is not handled. Therefore, it is not possible to directly design the digital phase compensator.

In the embodiment, in order to solve the above problem 1, a special QE algorithm for a Sign Definite Condition (SDC) is used. Also, in order to solve the above problem 2, a parameter region Rc of the analog phase compensator satisfying the specifications is designed by the special QE algorithm for the SDC.

Various conditions for designing the control system are preferably described. The SDC may be defined as follow expression 21.

∀x(L<x≦U→f(x)>0), xε [symbol] , [expression 21]

in the expression 21, f(x) is represented by a n-th order real coefficient polynomial. With respect to the SDC defined in the expression 20, a quantifiers symbol is effectively eliminated. As one example of eliminating the quantifiers symbol, by referring to ‘H. Iwane, H. Higuchi, and H. Anai, “An effective implementation of a special quantifier elimination for a sign definite condition by logical formula simplification,” CASC., to appear, 2013’, an expression 22 is presented.

$$∀ ω ( {ω}^{2} + b ω + K > 0 ) {}^{QE ALGORITHM} {b}^{2} - 4 K < 0 \qquad [ expression 22 ]$$

In the expression 22, ω denotes a variable with the quantifiers symbol, and b and K denote variables without the quantifiers symbols. In the expression 22, ω is eliminated by the QE algorithm.

By replacing the pulse transfer function K[z] representing the frequency characteristic specification indicated by the expression 20 with K(s), the expression 22 results in the SDC. The circuit constant related to the DC-DC converter 1 is substituted into L(jω), and the above described QE algorithm is applied, so that the parameter region Rc satisfying the specification of K(s) is acquired.

As indicated in the expression 23, it is considered to approximate the frequency characteristics of an analog phase compensator Kc(s) to a digital phase compensator Kd(z) by the Tustin conversion.

$${K}_{c} ( s ) = \frac{{b}_{c 0} s + {b}_{c 1}}{s + {a}_{c 1}} {{}^{Tustin Conversion}}_{s = \frac{2}{h} \frac{z - 1}{z + 1}} {K}_{d} ( z ) = \frac{{b}_{d 0} z + {b}_{d 1}}{z + {a}_{d 1}} \qquad [ Expression 23 ]$$

That is, by substituting an expression 25 into the analog phase compensator Kc(s) (the expression 24) and performing the Tustin conversion, the expression 26 is acquired.

$$\begin{matrix}{K}_{c} ( s ) = \frac{{b}_{c 0} s + {b}_{c 1} }{s + {a}_{c 1}} & \{ Expression 24 ] \\ s = \frac{2}{h} \frac{z - 1}{z + 1} & [ Expression 25 ] \\ {K}_{d} ( z ) = \frac{\frac{{b}_{c 1} h + 2 {b}_{c 0}}{{a}_{c 1} h + 2} z + \frac{{b}_{c 1} h - 2 {b}_{c 0}}{{a}_{c 1} h + 2}}{z + \frac{{a}_{c 1} h - 2}{{a}_{c 1} h + 2}} & [ Expression 26 ]\end{matrix}$$

After that, the coefficients a_{d1}, b_{d0}, and b_{d1} of the digital phase compensator Kd(z) are represented by the coefficients a_{c1}, b_{c0}, and b_{c1} of the analog phase compensator Kc(s).

$$\{ \begin{matrix}{a}_{d 1} = \frac{{a}_{c 1} h - 2}{{a}_{c 1} h + 2} \\ {b}_{d 0} = \frac{{b}_{c 1} h + 2 {b}_{c 0}}{{a}_{c 1} h + 2} \\ {b}_{d1} = \frac{{b}_{c 1} h - 2 {b}_{c 0}}{{a}_{c 1} h + 2}\end{matrix} \qquad [ Expression 27 ]$$

Accordingly, it is possible to represent the coefficients a_{c1}, b_{c0}, and b_{c1} of the analog phase compensator Kc(s) by the coefficients a_{d1}, b_{d0}, and b_{d1}, respectively.

$$\{ \begin{matrix}{a}_{c 1} = \frac{2}{h} \frac{1 + {a}_{d 1}}{1 - {a}_{d 1}} \\ {b}_{c 0} = \frac{{b}_{d 0} - {b}_{d 1} }{1 - {a}_{d 1}} \\ {b}_{c 1} = \frac{2}{h} \frac{{b}_{d 0} + {b}_{d 1}}{1 - {a}_{d 1}}\end{matrix} \qquad [ Expression 28 ]$$

By substituting this expression 28 into a polynomial of the parameter region Rc, it is possible to acquire the parameter region Rd.

Due to an approximation by the Tustin conversion, it is possible to acquire sufficient accuracy at a frequency band sufficiently closer to a sampled frequency. Since the control band (approximately 3 kHz) preferable for the DC-DC convertor 1 is sufficiently lower than the sampled frequency (90 kHz), it is possible to acquire the digital phase compensator Kd(z) in which the analog phase compensator Kc(s) obtained by the QE algorithm is approximated at sufficient accuracy.

Accordingly, it is possible to acquire the parameter region Rd of the digital phase compensator Kd(z) which takes over the frequency characteristics, from the parameter Rc of the analog phase compensator Kc(s). It is possible to acquire the parameter region Rd of the digital phase compensator Kd(z) for the manufacture dispersion for each of the DC-DC converters 1. A common region ARd is acquired from a region which satisfies the specifications and is overlapped with the parameter regions Rd, respectively, for multiple digital phase compensators Kd(z).

The sampling period h of the DC-DC converter 1 is approximately 100 kHz and is significantly short. It is important to acquire precisely the parameter region Rc by using the QE algorithm. Also, the Tustin conversion is known as the most accurate conversion from analog data to digital data at the present moment. By converting the parameter region Rc precisely acquired into the parameter region Rd by the Tustin conversion, it is possible to acquire the parameter region Rd of the digital phase compensator Kd(z) at higher accuracy.

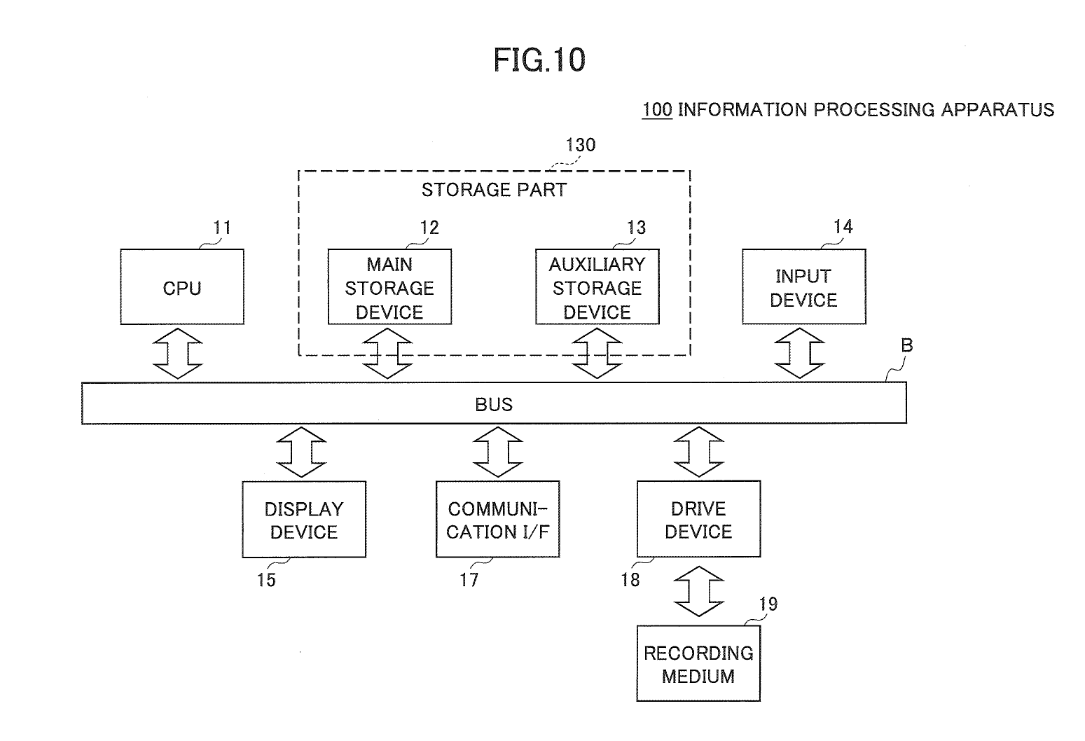

A parameter determination method according to the embodiment is conducted by an information processing apparatus 100 that includes a hardware configuration as illustrated in FIG. 10. FIG. 10 is a diagram illustrating the hardware configuration of the information processing apparatus. In FIG. 10, the information processing apparatus 100 is regarded as a terminal controlled by a computer, and includes a processor as a Central Processing Unit (CPU) 11, a main storage device 12, an auxiliary storage device 13, an input device 14, a display device 15, a communication interface (I/F) 17, and a drive device 18, which are mutually connected to each other via a bus B.

The CPU 11 controls the information processing apparatus 100 in accordance with programs stored in the main storage device 12. As the main storage device 12, a Random Access Memory (RAM) and a Read Only Memory (ROM), or the like is used to store or temporarily retain a program to be executed by the CPU 11, data for a process by the CPU 11, data acquired in the process by the CPU 11, and the like.

As the auxiliary storage device 13, a Hard Disk Drive (HDD) or the like may be used to store various programs for performing various processes and multiple sets of data. A part of the programs stored in the auxiliary storage device 13 is loaded into the main storage device 12, and is executed by the CPU 11, so that the various processes are realized. A storage part 130 may include the main storage device 12 and/or auxiliary storage device 13.

The input device 14 includes a mouse, a keyboard, and the like. The input device 14 is used by a user to input various information items for the processes conducted by the information processing apparatus 100. The display device 15 displays various information items under control of the CPU 11. The communication I/F 17 communicates via a wired or wireless network. Communication by the communication I/F 17 is not limited to wireless communication or wired communication.

For example, the programs for realizing the processes conducted by the information processing apparatus 100 may be provided to the information processing apparatus 100 with a recording medium 19 such as a Compact Disc Read-Only Memory (CD-ROM).

The drive device 18 interfaces between the recording medium 19 (which may be the CD-ROM or the like) set into the drive device 18 and the information processing apparatus 100.

Also, the recording medium 19 stores the programs that realize various processes according to the embodiment. The programs stored in the recording medium 19 are installed into the information processing apparatus 100. The installed programs becomes executable by the information processing apparatus 100.

It is noted that the recording medium for storing the programs is not limited to the CD-ROM, and any types of computer-readable recording media may be used. As the computer-readable recording medium, a Digital Versatile Disk (DVD), a portable recording medium such as a Universal Serial Bus (USB) memory, or a semiconductor memory such as a flash memory may be used.

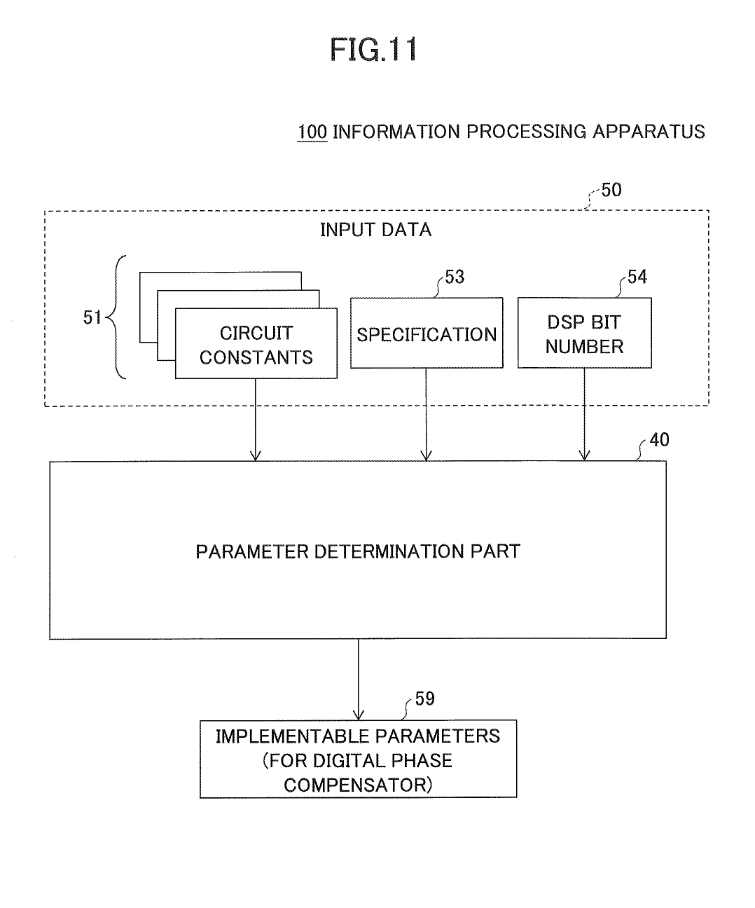

FIG. 11 is a diagram illustrating a brief configuration of the information processing apparatus. In FIG. 11, the information processing apparatus 100 includes multiple circuit constants 51, which are prepared by the developer, a specification 53, and a DSP bit number 54.

The input data 50 include the multiple circuit constants 51. Each of the multiple circuit constants 51 corresponds to a set of multiple parameters r_{q}, r_{d}, r_{L}, L, and C and indicates different values of the parameters based on the manufacturing dispersion. The multiple circuit constants 51 are regarded as data files each listing parameter values. The specification 53 is regarded as a data file which includes data indicating the frequency characteristics and at least the constraints of the above described specifications 1 through 4. The DSP bit number 54 indicates a bit number of the DSP 4 which is designed.

The parameter determination part 40 conducts a parameter determination part process, which will be described later, by using the input data 50, and outputs implementable parameters 59. By using the multiple circuit constants 51, the implementable parameters 59 corresponding to the manufacturing dispersion of the DC-DC converters 1 are acquired.

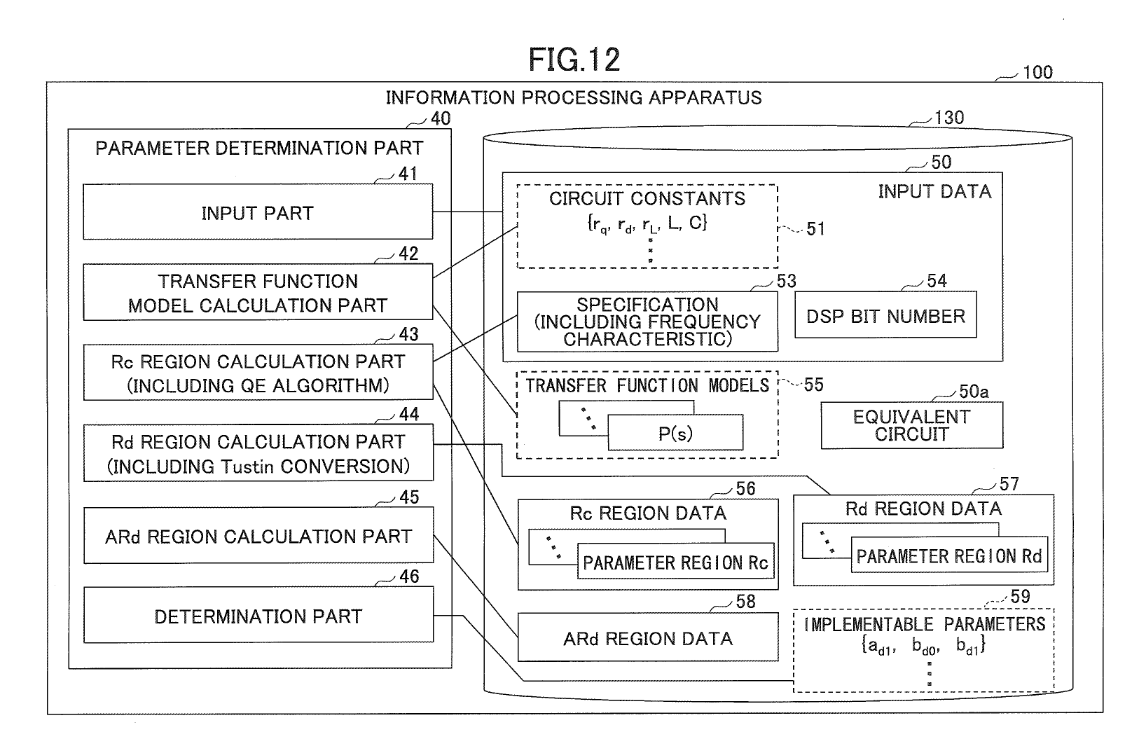

FIG. 12 is a diagram illustrating a functional configuration example of the information processing apparatus. In FIG. 12, the information processing apparatus 100 includes a parameter determination part 40. The storage part 130 stores the input data 50, the equivalent circuit 50a, multiple transfer function models 55, Rc region data 56, Rd region data 57, ARd region data 58, the implementable parameters 59, and the like.

The parameter determination part 40 further includes an input part 41, a transfer function model calculation part 42, a Rc region calculation part 43, a Rd region calculation part 44, an ARd region calculation part 45, and a determination part 46. The input part 41, the transfer function model calculation part 42, the Rc region calculation part 43, the Rd region calculation part 44, the ARd region calculation part 45, and the determination part 46 correspond to respective processes conducted by the CPU 11 executing corresponding programs.

The input part 41 acquires the input data 50 from the developer and stores the data in the storage part 130. The input data 50 includes the multiple circuit constants 51, the specification 53, and the DSP bit number 54.

Each of the circuit constants 51 corresponds to a combination of parameter values of respective circuit constants inside of the equivalent circuit 50a (FIG. 3) representing the DC-DC converter 1. The developer estimates the manufacturing dispersion, so that the parameter values are acquired. That is, each of the circuit constants 51 indicates values of r_{q}, r_{d}, r_{L}, L, and C as the combination. The circuit constants 51 indicate combinations of different values depending on the manufacture dispersions.

The equivalent circuit 50a is created by the developer, and is stored in the storage part 130. By applying the parameter values to the equivalent circuit 50a for each of the circuit constants 51, it is possible to realize various equivalent circuits in which the manufacture dispersions are reflected. By the multiple circuit constants 51 and the equivalent circuit 50a, multiple equivalent circuits are represented based on different manufacturing dispersions. Instead of the circuit constants 51, the multiple equivalent circuits 50a in which the different manufacturing dispersions are reflected are stored in the storage part 130 through the input part 41.

The specification 53 includes the frequency characteristics. As an example, the above described specifications 1 through 4 may be included in the specification 53. The DSP bit number 54 indicates the bit number of the DSP 4 to be designed. The DSP 4 corresponds to the digital phase compensator.

The transfer function model calculation part 42 creates the transfer function model 55 for each of the manufacture dispersions of the DC-DC converters 1 based on the multiple circuit constants 51 and the equivalent circuit 50a (that is, based on the multiple equivalent circuits in each of which a different manufacture dispersion is reflected) by using a State-Space Averaging Method. The multiple transfer function models 55 are created in the storage part 130.

The Rc region calculation part 43 calculates the parameter region Rc of the analog phase compensator satisfying the specification 53 by using each of the multiple transfer function models 55 and by the special QE algorithm for the SDC. Multiple parameter regions Rc are calculated, and stored in the storage part 130. The Rc region data 56 indicate the multiple parameter regions Rc. Each of the multiple parameter regions Rc is represented by the polynomial.

The Rd region calculation part 44 calculates the parameter region Rd by conducting the Tustin conversion with respect to each of the multiple parameter regions Rc which are calculated by the Rc region calculation part 43. The multiple parameter regions Rd are acquired as the same count as the parameter region Rc calculated by the Rc region calculation part 43. The Rd region data 57 indicate the multiple parameter regions Rd. Each of the multiple parameter regions Rd is represented by the polynomials.

The ARd region calculation part 45 acquires the common region ARd among the multiple parameter regions Rd acquired by the Rd region calculation part 44. The ARd region data 58 indicating the common region ARd is stored in the storage part 130.

The determination part 46 determines based on the DSP bit number 54 whether there is an implementable parameter 59 of the DSP 4 in the common region ARd calculated by the ARd region calculation part 45. When there is the implementable parameter 59 of the DSP 4, The determination part 46 stores one or more implementable parameters 59 in the storage part 130. Also, the determination part 46 may display the common region ARd at the display device 15, and may indicate the one or more implementable parameters 59 in the common region ARd. Alternatively, the one or more implementable parameters 59 may be listed and displayed at the display device 15.

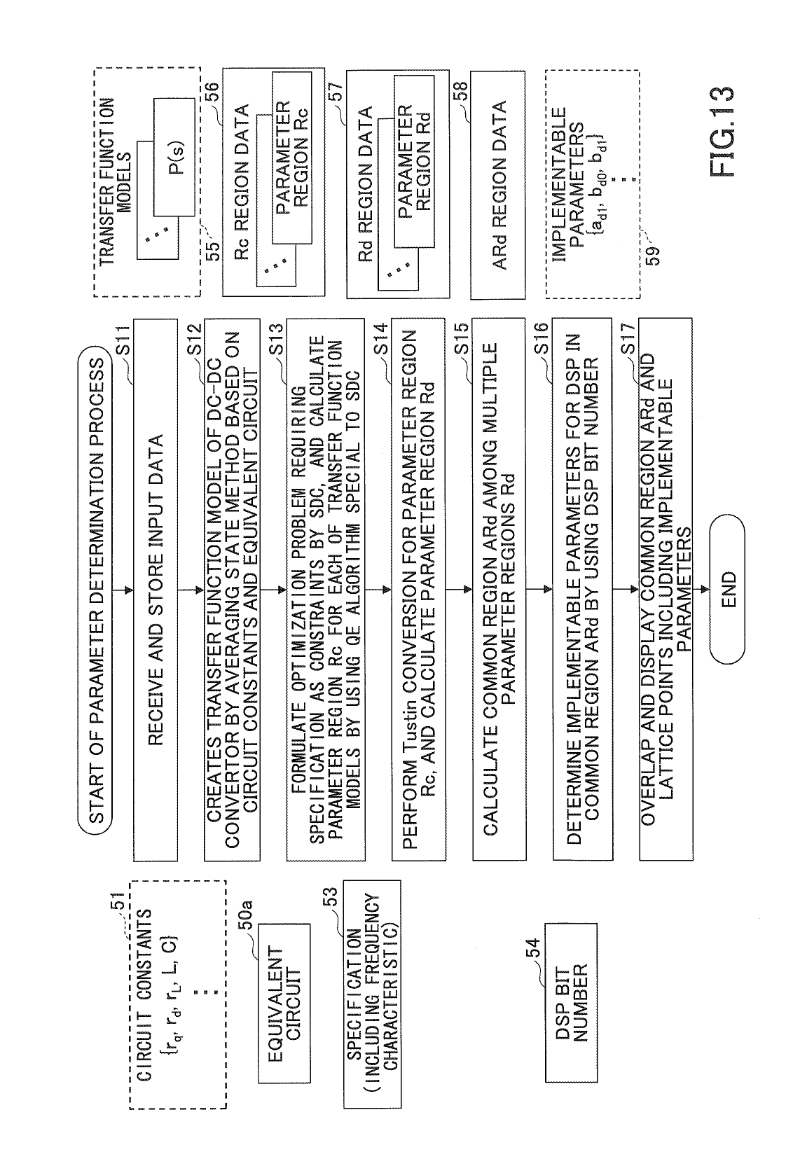

Next, a parameter determination process conducted by the parameter determination part 40 will be described. FIG. 13 is a diagram for explaining an example of the parameter determination process. In FIG. 13, the input part 41 of the parameter determination part 40 receives the input data 50 from the developer, and stores the input data 50 in the storage part 130 (step S11). The input data 50 include data of the circuit constants 51, the specification 53, and the DSP bit number 54.

The transfer function model calculation part 42 creates the transfer function p(s) for each of the manufacturing dispersions by using the circuit constants 51 and the equivalent circuit 50a, and creates a model of the DC-DC converter 1 for each of the manufacture dispersions (step S12). The transfer function model calculation part 42 sequentially selects one from the multiple circuit constants 51, and creates one transfer function 55 (corresponding to the transfer function p(s)) based on the equivalent circuit 50a and the selected circuit constant 51 by the State-Space Averaging Method. With respect to n circuit constants 51, n transfer function models are created.

The Rc region calculation part 43 formulates the optimization problem in which the specification 53 is indicated as the constraints, and calculates the parameter region Rc for each of the transfer function models 55 by using the special QE algorithm for the SDC (step S13). With respect to n transfer function models 55, n parameter regions Rc are acquired. Each of the parameter regions Rc is represented by the polynomial, and indicates the parameter region of the analog phase compensator.

The Rd region calculation part 44 calculates the parameter Region Rd by selecting one among the multiple parameter regions Rc in the storage part 130 and by conducting the Tustin conversion (step S14). Based on n parameter regions Rc, by the Tustin conversion, n parameter regions Rd are calculated and are stored in the storage part 130.

Next, the ARd region calculation part 54 calculates the common region ARd among the multiple parameters Rd (step S15). By calculating a region which is included in all multiple parameter regions Rd, the common region ARd is acquired. The common region ARd is represented by the polynomial, and is stored as the ARd region data 58 in the storage part 130.

After that, the determination part 46 calculates the parameters of the DSP 4 by using the DSP bit number 54, and determines whether the parameters of the DSP 4 are included in the common region ARd acquired by the ARd region calculation part 54, so as to determine whether control is realized in which the frequency characteristics defined by the specification 53 are satisfied, regardless of the manufacturing dispersions of the DC-DC converters 1, and whether the DSP 4 is implemented (step S16).

The determination part 46 acquires the implementable parameters 59 by overlapping parameter values represented by the DSP 4 with lattice points in the common region ARd. The acquired implementable parameters 59 indicate desired digital phase compensator parameters.

The determination part 46 overlays and displays the common region ARd and the lattice points including the implementable parameters 59 (step S17). The implementable parameters 59 may be listed and displayed.

When the implementable parameters 59 are not acquired, no lattice point being overlaid with the common region ARd is displayed. Hence, it is possible for the developer to easily determine that the DSP bit number 54 indicated by the developer is not realized. In this case, the developer re-sets the circuit constants 51 and/or DSP bit number 54, and has the information processing apparatus 100 conduct the above described parameter determination process.

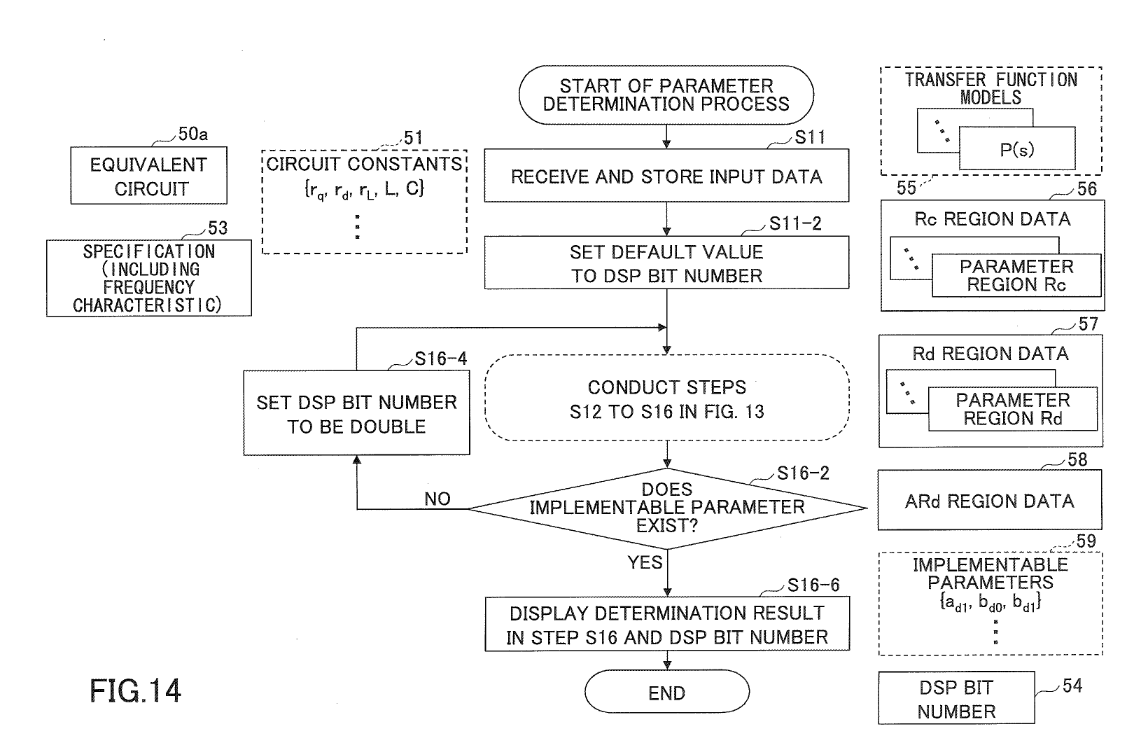

Next, another example of the parameter determination process, in which output results indicate the DSP bit number 54, and the implementable parameter 49 which satisfy the constraints regardless of the manufacture dispersions, will be described. FIG. 14 is a flowchart for explaining the another example of the parameter determination process.

In FIG. 14, the input part 41 of the parameter determination part 40 receives the input data 50 from the developer, and stores the input data 50 to the storage part 130 (step S11). The input data include the circuit constants 51 and the specification 53.

The DSP bit number 54 is not included in the input data 50. Alternatively, when the developer sets the DSP bit number 54, steps S12 through S17 in FIG. 13 are conducted. When the DSP bit number 54 is not indicated by the developer, the following process may be conducted.

The input part 41 sets a default value to the DSP bit number 54 (step S11-2). The default value may be 8 bits. After that, processes in the steps S12 through S16 in FIG. 13 are conducted.

After the process of step S16, the determination part 46 determines whether there is the parameter of the DSP 4 in the common region ARd (step S16-2). The determination part 46 determines that there is no implementable parameter 59, when the implementable parameter 59 is empty in the storage part 130. On the other hand, the determination part 46 determines that there is one or more implementable parameters 59 when the implementable parameter 59 is not empty in the storage part 130. In this case, the one or more implementable parameters 59 are the desired digital phase compensator parameters.

If there is no implementable parameter 59, the determination part 46 sets the DSP bit number 54 double (step S16-4). After that, the processes of steps S12 through S16 in FIG. 13 are repeated.

On the other hand, when there is one or more implementable parameters 59, the determination part 46 displays a determination result of step S16 and the DSP bit number 54 (step S16-6). The common region ARd and the parameter values presented by the DSP 4 may be overlaid with each other, and a graph indicating the common region ARd and the parameter values of the DSP 4 may be displayed at the display device 15. Alternatively, the implementable parameters 59 may be displayed. In this case, the DSP bit number 45 is displayed.

In step S16-4, as a result of setting the DSP bit number 54 double, if the DSP bit number 54 exceeds a predetermined bit number (which may be 32 bits), it is determined that the implementable parameters 59 are not obtained. In this case, a message indicating that there is no implementable parameter or the like may be displayed at the display device 15.

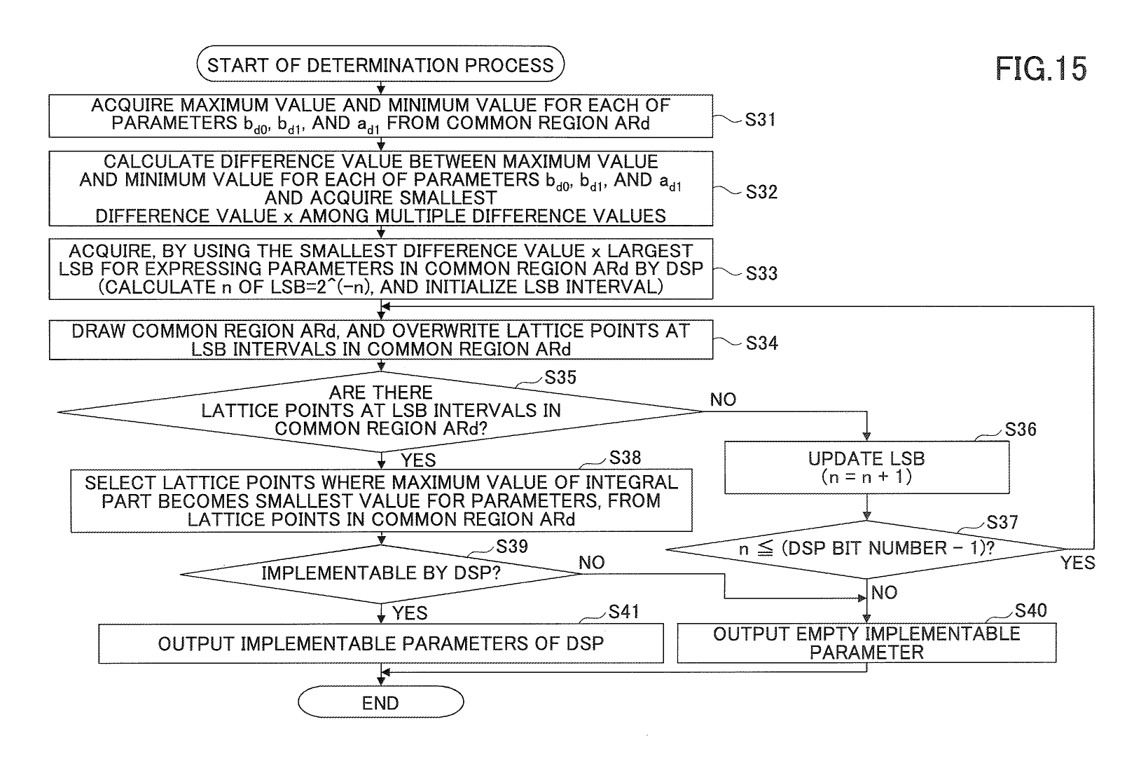

Next, an example of a determination process conducted by the determination part 46 will be described. FIG. 15 is a flowchart for explaining the determination process. In FIG. 15, the determination part 46 acquires a maximum value and a minimum value for each of the parameters b_{d0}, b_{d1}, and a_{d1} from the common region ARd (step S31).

After that, the determination part 46 acquires a difference value between the maximum value and the minimum value for each of the parameters b_{d0}, b_{d1}, and a_{d1}, and obtains a least difference value x from among multiple difference values (step S32).

x: =min{(max value−min value) of b_{d0}, (max value−min value) of b_{d1}, (max value−min value) of a_{d1}} [Expression 29]

Next, the determination part 46 acquires, by using the least difference value x, a longest LSB interval for the DSP 4 to represents values of the parameters in the common region ARd (step S33). That is, from the following expression:

LSB=2̂(−n)(n=0, 1, 2, . . . ),

n is acquired where the LSB interval becomes the longest, and the LSB interval is initialized.

The determination part 46 draws the common region ARd, and overwrites the lattice points of the LSB intervals on the common region ARd (step S34), and determines whether there is one or more lattice points of the LSB intervals in the common region ARd (step S35). If there is no lattice point in the common region ARd, the determination part 46 updates the LSB interval (step S36). That is, n is incremented by 1, and the LSB interval becomes ½ length.

The determination part 46 determines whether n is less than or equal to the DSP bit number (step S37). When n is less than or equal to a value resulted from decreasing one from the DSP bit number 54, the determination part 46 goes back to step S34, re-draws the lattice points at the updated LSB intervals, and then, repeats the above described processes in the same manner. When n is greater than the value resulted from decreasing one from the DSP bit number 54, the determination part 46 advances to step S40, and outputs the implementable parameter 59 indicating empty.

On the other hand, when there is one or more lattice points in the common region ARd, the determination part 46 selects a lattice point, in which a maximum value in integer parts of the parameters b_{d0}, b_{d0}, and a_{d1} becomes a smallest value, among the one or more lattice points in the common region ARd (step S36).

The determination part 46 determines whether the selected lattice point is implementable for the DSP (step S39). When the selected lattice point is not implementable for the DSP 4, the determination part 46 determines that there is no desired digital phase compensator parameter in a case of the DSP bit number 54, and outputs the implementable parameter 59 indicating empty (step S40). The determination part 46 terminates this determination process.

On the other hand, when the selected lattice point is implementable for the DSP 4, the determination part 46 outputs the selected lattice point as the implementable parameter 54 (step S41), and terminates this determination process. A value of the selected lattice point becomes a value of the parameter having the longest LSB and the least integer part, and also becomes the desired digital phase compensator parameter.

In step S39, the determination part 46 displays the value of the lattice point selected in step S38 at the display device 15 for the developer to determine. Alternatively, the determination part 46 may determine based on the specification 53 of the DSP 4.

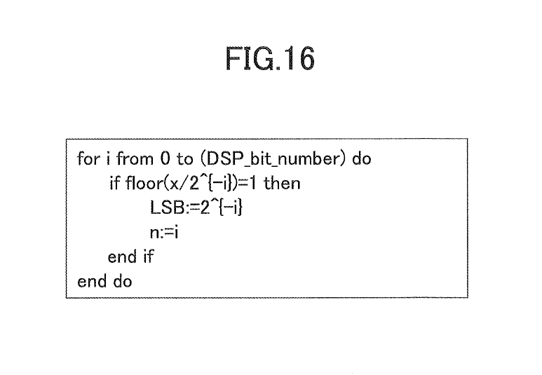

Next, a process for acquiring the longest LSB interval in step S33 will be described. FIG. 16 is a diagram illustrating a program description example for conducting the process in step S33 in FIG. 15. The program description is not limited to the program description example in FIG. 16.

In FIG. 16, the determination part 46 sets 0 as an initial value to a variable i, and repeats processes below until the variable i reaches the DSP bit number 54.

The determination part 46 divides the least difference value x acquired in step S32 by 2̂(−i), and truncates digits beyond a decimal point. When a result indicates 1, the LSB interval is set to 2̂(−i), and n is set to the variable i. On the other hand, when the result does not indicate 1, the determination part 46 does not change the LSB interval and the variable i.

Every time the variable i is incremented by 1, the determination part 46 conducts this process, and terminates the process in step S33 when the variable i becomes the DSP bit number 54.

Next, calculation result examples of the Rc region calculation part 43, the Rd region calculation part 44, and the ARd region calculation part 45.

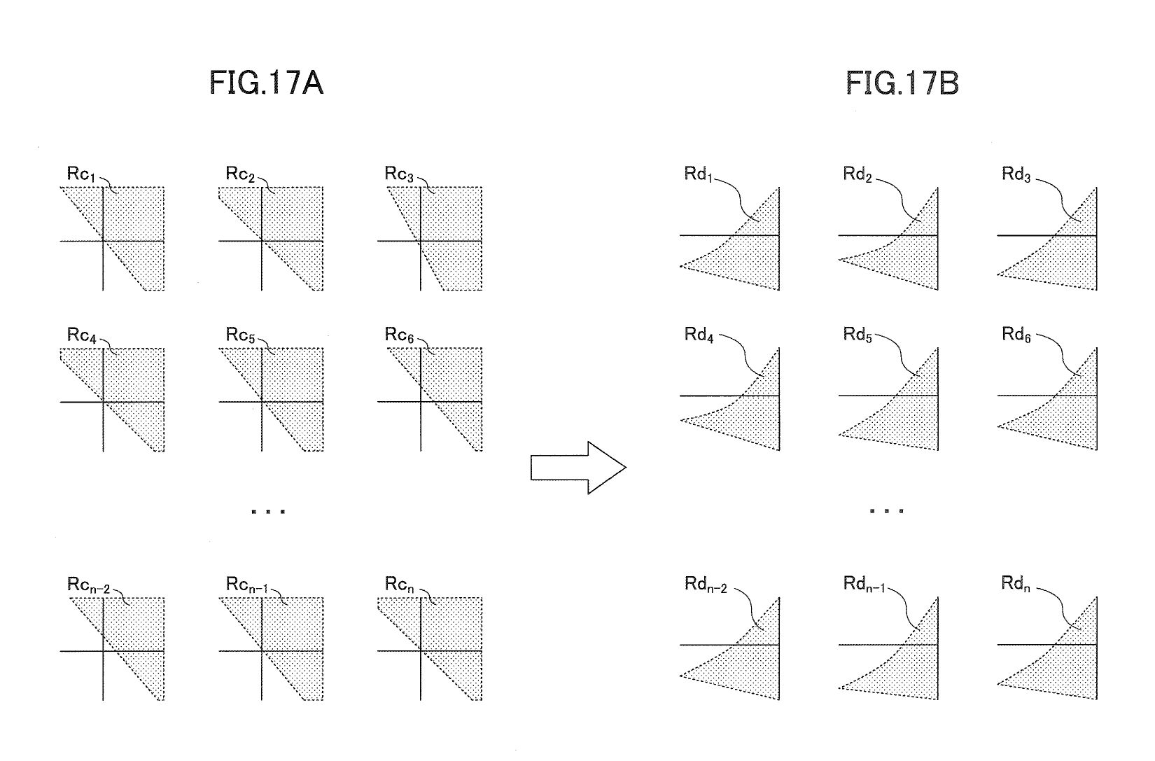

FIG. 17A and FIG. 17B are diagrams illustrating calculation results of the parameter regions Rc and Rd for each of the manufacture dispersions. FIG. 17A illustrates a result example of the parameter regions Rc calculated by the Rc region calculation part 43. Each of the parameter regions Rc is represented by the polynomial which is acquired for each of the circuit constants 51 by estimating the manufacture dispersions.

In a case of n circuit constants 51, n polynomials representing n parameter regions Rc₁, Rc₂, . . . Rcₙ are generated. The parameter determination part 41 may draw and display the n parameters Rc₁, Rc₂, . . . Rcₙ at the display device 15 in response to an instruction of the developer.

FIG. 17B illustrates a result example of the parameter regions Rd calculated by the Rd region calculation part 44. Each of the parameter regions Rd is represented by the polynomial which is acquired for each of the circuit constants 51 by estimating the manufacture dispersions.

In a case of n parameter regions Rc, n polynomials representing n parameter regions Rd₁, Rd₂, . . . Rdₙ are generated. The parameter determination part 41 may draw and display the n parameters Rd₁, Rd₂, . . . Rdₙ at the display device 15 in response to an instruction of the developer.

If the parameter region Rc₁ is acquired by the circuit constant 51 which is obtained by estimating the manufacture dispersion of a DC-DC converter A, the parameter region Rd₁ corresponds to the parameter region of the DSP 4 for the DC-DC converter A.

If the parameter region Rc₂ is acquired by the circuit constant 51 which is obtained by estimating the manufacture dispersion of a DC-DC converter B, the parameter region Rd₂ corresponds to the parameter region of the DSP 4 for the DC-DC converter B.

Other parameter region Rc₃ to Rcₙ and other parameter region Rd₃ to Rdₙ are explained in the same manner.

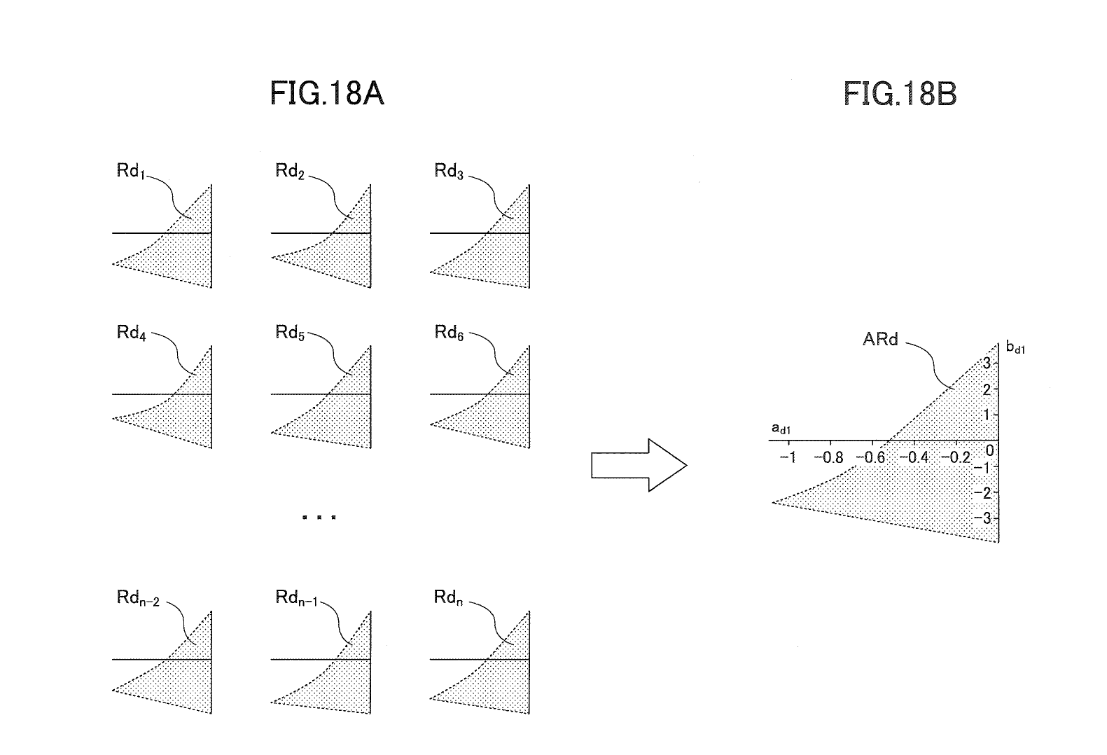

FIG. 18A and FIG. 18B are diagrams for explaining a calculation result example of the common region ARd. FIG. 18A illustrates the result example of n parameter regions Rd₁ to Rdₙ calculated by the Rd region calculation part 44 as the same as that in FIG. 17B. FIG. 18B illustrates a result example of calculation of the common region ARd among the multiple parameter regions Rd. The common region ARd corresponds to a region being included in each of n parameter regions Rd₁ to Rdₙ.

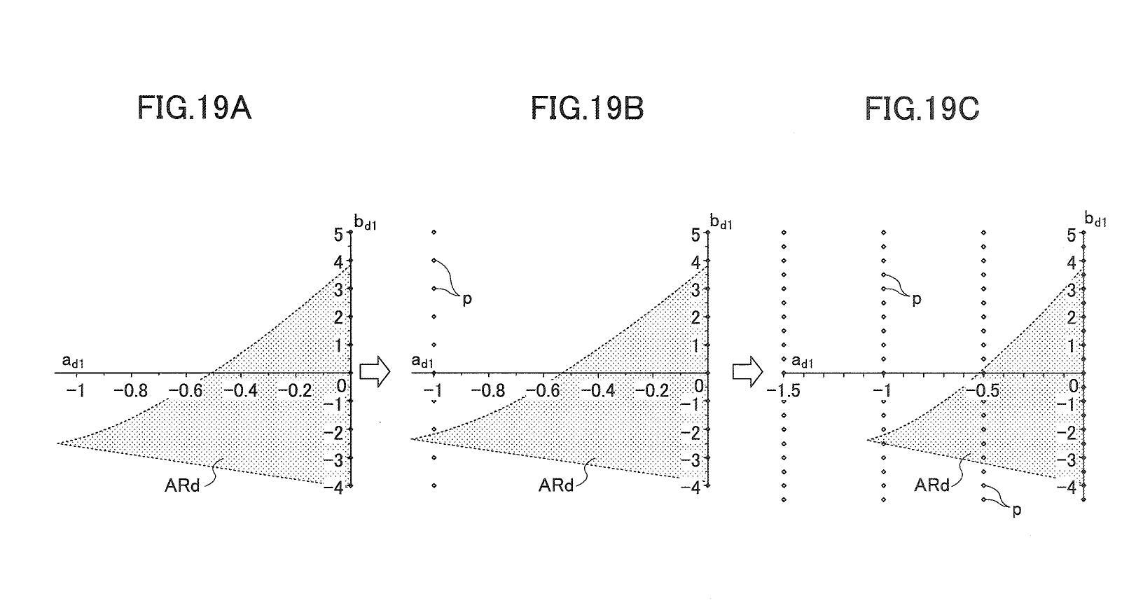

FIG. 19A, FIG. 19B, and FIG. 19C are diagrams illustrating result examples of the lattice points based on the LSB intervals. FIG. 19A corresponds to FIG. 18B, and illustrates a state before the determination part 46 calculates lattice points p at the LSB intervals. FIG. 19B illustrates a result example of the lattice points p calculated when the LSB interval is 1 (LSB=2̂(−n), n=0). In FIG. 19B, there is no lattice point p included in the common region ARd.

Accordingly, the determination part 46 changes the LSB interval to 0.5 (LSB=2̂(−n), n=1), and calculates the lattice point p. In this case, as a result, as depicted in FIG. 19C, there are multiple lattice points p in the common region ARd. The determination part 46 selects a lattice point p in which the maximum value in the integer parts of values of the multiple lattice points p becomes the smallest value, among the multiple lattice points p existing in the common region ARd. When a value of the selected lattice point p is implementable for the DSP 4, the determination part 46 outputs the implementable parameter 59 indicating the value of the lattice point p.

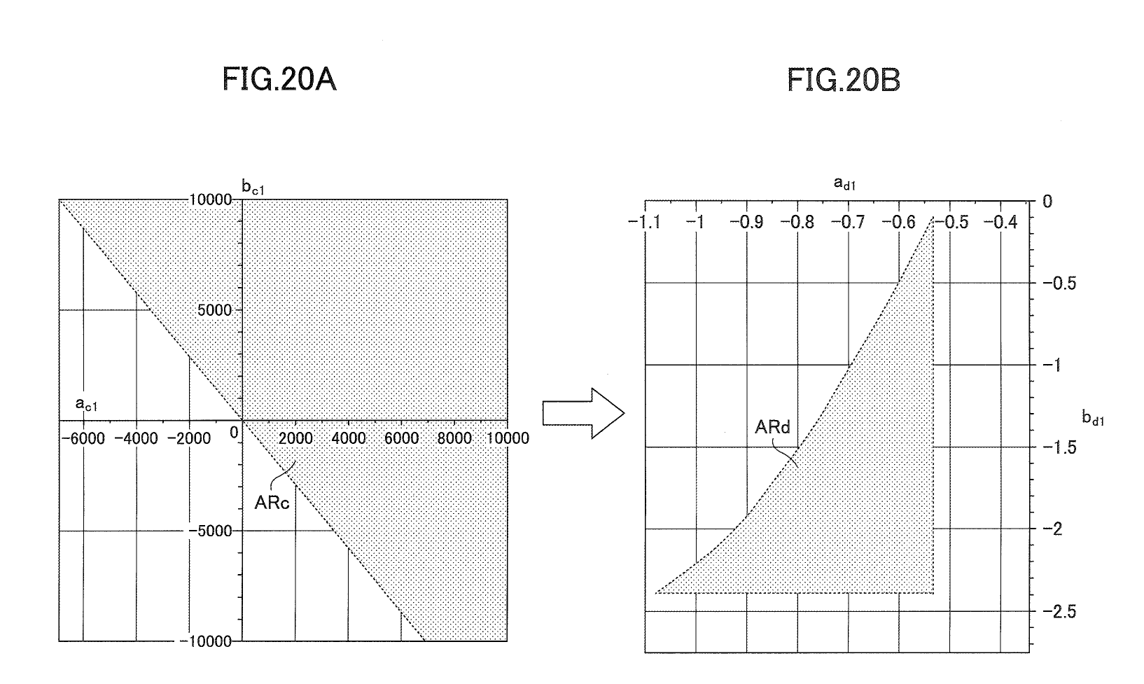

Instead of acquiring the parameter regions Rd with respect to the parameter regions Rc, as illustrated in FIG. 20A and FIG. 20B, a common region ARc among all parameter regions Rc may be calculated, and the common region ARd may be acquired by conducting the Tustin conversion with respect to the common region ARc.

As described above, in the embodiment, assumed manufacture dispersions are estimated beforehand by the parameters representing the circuit constants r_{q}, r_{d}, r_{L}, L, and C of the equivalent circuit 50a, models of the multiple DC-DC converters 1 having different manufacture dispersions are acquired by the State-Space Averaging Method. By the special QE algorithm for the SCD 4 regarding these modes, the parameter regions Rc of the analog phase compensator satisfying the specification 53.

The parameter regions Rd of the digital phase compensator are acquired by conducting the Tustin conversion with respect to the parameter regions Rc. By calculating the common region ARd included in all acquired parameter regions Rd, it is possible to obtain the parameter region for the digital phase compensator objective to control any one of the DC-DC converters 1 having the different manufacture dispersions.

Furthermore, by representing points implementable for the DSP 4 as the lattice points p and by overlapping the points on the common region ARd, the values of the parameters of the desired digital phase compensator are acquired so that the frequency characteristics are not changed due to the fixed point of the DSP 4. Hence, re-adjustment may not be conducted for the digital phase compensator for each of the DC-DC converters 1, and it is possible to reduce manufacturing steps for the mass production.

As described above, in the embodiment, the information processing apparatus 100 includes the parameter determination part 40. Alternatively, the parameter determination part 40 may be realized by a cloud computing architecture.

As an example, the DC-DC back convertor is explained above. The embodiment may be applied to a forward converter, a half bridge convert, and full bridge converter.

Also, it is possible to apply the embodiment to a device design of a feedback control system in which the followings are assumed:

(1) A control model of a control subject is given as a transfer function having one input and one output, the transfer function being acquired based on a model including physical parameters (the circuit constants 51 above) such as the equivalent circuit 50a,
(2) Its controller design problem is given as an open loop shaping problem by the digital phase compensator, and
(3) A gain cross frequency, which is to be acquired as an open loop specification, is sufficiently lower than a Nyquist frequency derived from a sampling frequency of a control system.

A device to be designed under the above assumptions may be the digital phase compensator, a magnetic levitation controller, or the like to control an angular rate of a load connected to a shaft of a DC motor.

In the embodiment described above, the Rc region calculation part 43 and the Rd region calculation part 44 correspond to a region specification part. The ARd region calculation part 45 and the determination part 46 correspond to an output part. The executable region, the parameter regions Rc and Rd, the common region ARd, and the like are regarded as ranges of the parameters, respectively.

In the embodiment, there may be further provided a compensator design supporting method performed in a computer, the method including: creating, by the computer, a transfer function model for each of manufacturing dispersions by using an equivalent circuit, multiple circuit constants, and a specification, the equivalent circuit representing a circuit controlled in a feedback control system, the multiple circuit constants being those with which the manufacturing dispersions of the circuit are estimated, the specification indicating frequency characteristics; acquiring, by the computer, a first parameter range of an analog circuit that controls the circuit satisfying the specification for each of the transfer function models, by formulating the specification as a Sign Definite Condition and by using a special Quantifier Elimination algorithm for the Sign Definite Condition; and acquiring, by the computer, a second parameter range of a digital circuit that controls the circuit, by conducting a digital conversion for each of the first parameter ranges.

In the embodiment, the above described compensator design supporting method may further include acquiring, by the computer, a common range included in each of the second parameter ranges converted from the first parameter ranges.

In the embodiment, in the compensator design supporting, the specification may be indicated by a non-convex function.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A parameter determination method comprising:
receiving information of a specification required for an output of a predetermined circuit;
receiving a first circuit constant and a second circuit constant which are set in elements included in an equivalent circuit of the predetermined circuit;
specifying, by a computer, a first range of a plurality of parameters which are to be set in a compensator that compensates the output based on the information of the specification and the first circuit constant;
specifying, by the computer, a second range of a plurality of parameters which are to be set in the compensator based on the information of the specification and the second circuit constant; and
outputting, by the computer, at least one of a parameter included in both the first range and the second range.

2. The parameter determination method as claimed in claim 1, wherein
the first range is defined by a range of the parameters where a first value of a first function satisfies the specification in which the first circuit constant, the parameters, and frequency are set in variables of the first function, and
the second range is defined by another range of the parameters where a second value of a second function satisfies the specification in which the second circuit constant, the parameters, and frequency are set in variables of the second function.

3. The parameter determination method as claimed in claim 2, further comprising:
acquiring, by the computer, a first parameter range and a second parameter range of an analog circuit that controls the predetermined circuit satisfying the specification, respectively, for a first transfer function corresponding to the first circuit constant and a second transfer function corresponding to the second circuit constant, by formulating the specification as a Sign Definite Condition and by using a special Quantifier Elimination algorithm for the Sign Definite Condition;
acquiring, by the computer, the first range by converting the first parameter range to a digital range; and
acquiring, by the computer, the second range by converting the second parameter range to the digital range.

4. The parameter determination method as claimed in claim 3, further comprising:
acquiring, by the computer, a common range included in the first range and the second range; and
outputting, by the computer, the parameters which are included in the common range and are acquired at calculation accuracy of the compensator.

5. A non-transitory computer-readable recording medium that stores a parameter determination program that causes a computer to execute a process comprising:
receiving information of a specification required for an output of a predetermined circuit;
receiving a first circuit constant and a second circuit constant which are set in elements included in an equivalent circuit of the predetermined circuit;
specifying a first range of a plurality of parameters which are to be set in a compensator that compensates the output based on the information of the specification and the first circuit constant;
specifying a second range of a plurality of parameters which are to be set in the compensator based on the information of the specification and the second circuit constant; and
outputting at least one of a parameter included in both the first range and the second range.

6. An information processing apparatus comprising:
a processor that executes a process that includes
receiving information of a specification required for an output of a predetermined circuit;
receiving a first circuit constant and a second circuit constant which are set in elements included in an equivalent circuit of the predetermined circuit;
specifying a first range of a plurality of parameters which are to be set in a compensator that compensates the output based on the information of the specification and the first circuit constant;
specifying a second range of a plurality of parameters which are to be set in the compensator based on the information of the specification and the second circuit constant; and
outputting at least one of a parameter included in both the first range and the second range.
